(19) United States
(12) Patent Application Publication
(10) Pub. No.: US 2026/0093877 A1
(43) Pub. Date: Apr. 2, 2026

(54) MODELING PATHOGEN TRANSMISSION IN A THREE-DIMENSIONAL ENVIRONMENT

(71) Applicant: The Boeing Company, Arlington, VA (US)

(72) Inventors: Craig Anthony Pepper, Brisbane (AU); Iain Simon Koolhof, Hobart (AU); Ozge Makbule Ozcakir, Melbourne (AU); Jason Wesley Armstrong, Brisbane (AU); Sheridyn Marie Milli, Brisbane (AU)

(21) Appl. No.: 19/264,692

(22) Filed: Jul. 9, 2025

Related U.S. Application Data
(60) Provisional application No. 63/702,513, filed on Oct. 2, 2024.

(51) Int. Cl. G06F 30/28

(52) U.S. Cl. CPC G06F 30/28

(57) ABSTRACT

A system for modeling pathogen transmission in a three-dimensional environment includes processing circuitry configured to implement a pathogen transmission modeling program stored in memory. The processing circuitry generates three-dimensional environment geometry and performs computational fluid dynamics to determine a three-dimensional vector field of air velocity vectors in the three-dimensional environment. Movements and properties of simulated persons within the three-dimensional environment are modeled and correlated with the three-dimensional vector field of air velocity vectors of the three-dimensional environment. The processing circuitry executes a dispersion model to simulate movement of a pathogen in the three-dimensional environment in accordance with the movements and properties of the simulated persons and the three-dimensional vector field of air velocity vectors. An epidemiological exposure model is executed to compute a risk of exposure of each simulated person, and an epidemiological infection model is executed to compute a risk of infection of each simulated person.

### CROSS REFERENCE TO RELATED APPLICATIONS

This application claims priority to U.S. Provisional Patent Application Ser. No. 63/702,513, filed Oct. 2, 2024, the entirety of which is hereby incorporated herein by reference for all purposes.

### FIELD

The present disclosure relates generally to systems and methods for studying the risk of pathogen transmission in three-dimensional environments, including in travel environments such as airport gates, ramps, and aircraft cabins.

### BACKGROUND

Global pandemics and seasonal epidemics affect the health of the travelling public, which can result in significant economic impacts on the commercial aviation industry. The operations of airlines, airports, and manufacturers are guided by public health and regulatory responses to disease threats to protect passenger and population health while balancing the potential financial impact to industry. A risk-informed, evidence-based understanding of the mechanistic dynamics of infectious disease transmission in air travel environments is needed to develop effective risk mitigation strategies for potential future pandemics, as well as for seasonal disease events.

### SUMMARY

According to an example of the present disclosure, a system for modeling pathogen transmission in a travel environment is provided. The system includes processing circuitry and memory that stores a pathogen transmission modeling program including a plurality of models. The processing circuitry is configured to implement the pathogen transmission modeling program, thereby causing the processing circuitry to generate a three-dimensional digital representation of the travel environment and perform computational fluid dynamics analysis to determine a three-dimensional vector field of air velocity vectors in the travel environment. Movements and properties of a plurality of simulated persons within the travel environment are modeled and correlated with the three-dimensional vector field of air velocity vectors of the travel environment via a common coordinate system. The processing circuitry is further configured to execute a dispersion model to simulate movement of a pathogen in the travel environment in accordance with the movements and properties of the simulated persons and the three-dimensional vector field of air velocity vectors, execute an epidemiological exposure model to compute a risk of exposure of each simulated person in the travel environment, and execute an epidemiological infection model to compute a risk of infection of the plurality of simulated persons in the travel environment. The processing circuitry is further configured to output an indication of the risk of exposure and risk of infection.

### BRIEF DESCRIPTION OF THE DRAWINGS

FIG. 1 is a schematic diagram of a computing system including one or more computing devices that execute a pathogen transmission modeling program for modeling pathogen exposure and/or infection risk in a travel environment.

FIG. 2 is a schematic diagram illustrating information flows between software components of the computing system of FIG. 1.

FIG. 3 shows an image displayed by the computing system of FIG. 1, including a perspective view of geometry representing a three-dimensional physical environment in which the exposure and/or infection risk is modeled.

FIG. 4 shows an image displayed by the computing system of FIG. 1, illustrating a top view of the three-dimensional physical environment in which the pathogen exposure and/or infection risk is modeled, showing movement of simulated persons within the environment.

FIG. 5 shows an image displayed by the computing system of FIG. 1, illustrating a perspective view of a generated mesh of a three-dimensional physical environment in which the pathogen exposure and/or infection risk is to be modeled.

FIG. 6 shows a display image illustrating a perspective view of air velocity vectors in a three-dimensional physical environment in which the pathogen exposure and/or infection risk is to be modeled.

FIG. 7 shows a display image illustrating a perspective view of dispersion of an aerosolized pathogen from a point source release in the three-dimensional physical environment during a modeling simulation for pathogen exposure and/or infection risk.

FIG. 8 shows a display image illustrating a perspective view of dispersion of an airborne pathogen in a three-dimensional physical environment during a modeling simulation for pathogen exposure and/or infection risk.

FIG. 9 shows a diagram of dispersion of a fomite-transmissible pathogen in a three-dimensional physical environment during a modeling simulation for pathogen exposure and/or infection risk.

FIG. 10 shows a diagram of exposure of simulated persons in a three-dimensional physical environment during a modeling simulation for pathogen exposure and/or infection risk.

FIG. 11 is a flow chart of a computerized method for computing exposure and/or infection risk in a travel environment, according to one example implementation of the present disclosure.

FIG. 12 illustrates an exemplary computing system that may be used to implement the computing system of FIG. 1.

### DETAILED DESCRIPTION

A system and method for modeling travel risk in pandemics are disclosed herein. The system can be used, for example, to model the risk of exposure and/or infection for individual travelers and employees in air travel environments and at transportation hubs. While the computing system may be used to model risk during period of relative normalcy when pathogen prevalence is relatively low, it can also be used to model pathogen transmission during periods of relatively high pathogen transmission, such as global disease outbreaks, seasonal disease events, and even during biowarfare attacks.

As introduction, the modeling framework and architecture of the computing system described herein are configured to enable flexibility in tailoring the system to model the risk associated with any infectious agent at any degree of fidelity in a systematic process. The framework implements a top-down approach with discrete partitioned sub-models that represent the various aspects of disease transmission and are able to be run independently.

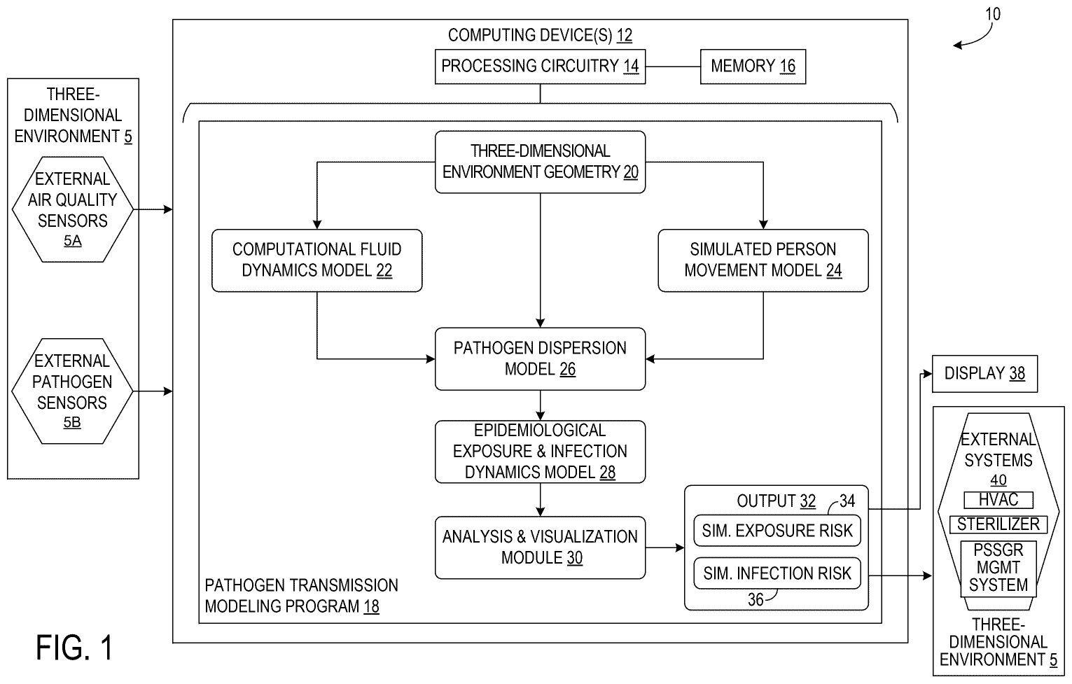

Turning to FIG. 1, a schematic diagram of a computing system 10 for modeling pathogen exposure and/or infection risk in a travel environment 5 is shown. The system includes one or more computing devices 12 that each have processing circuitry 14 such as a central processing unit, as well as associated memory 16 used by the processing circuitry 14. The memory 16 can include non-volatile memory such as a mass storage device, as well as volatile memory such as RAM. The memory 16 stores instructions for a pathogen transmission modeling program 18, which when executed by the processing circuitry 14 cause the processing circuitry to perform the functions described herein.

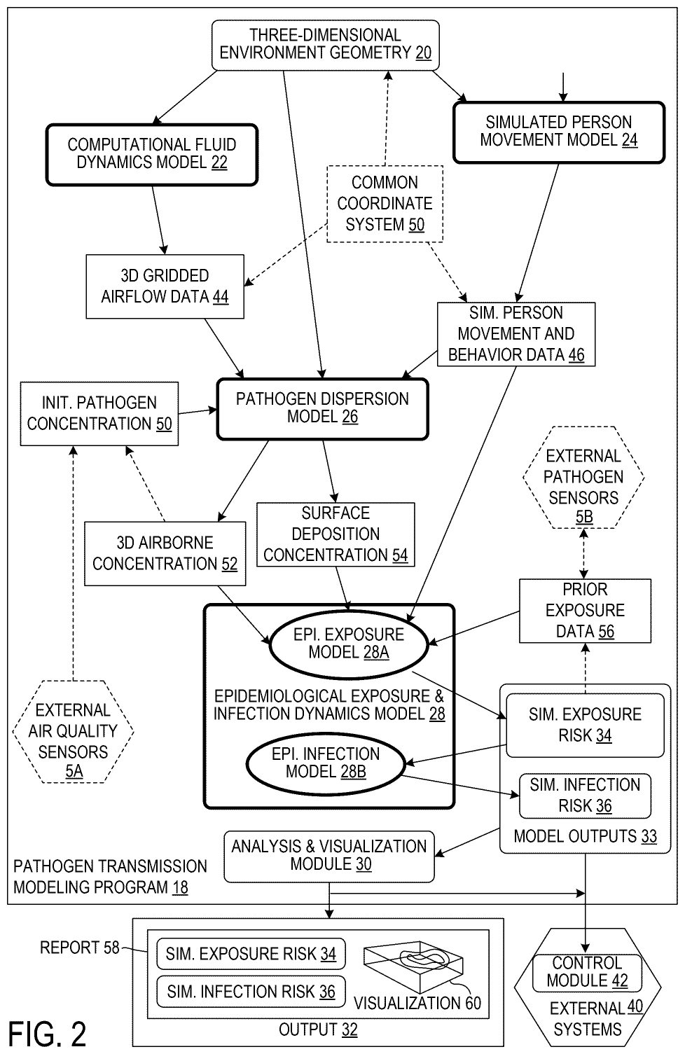

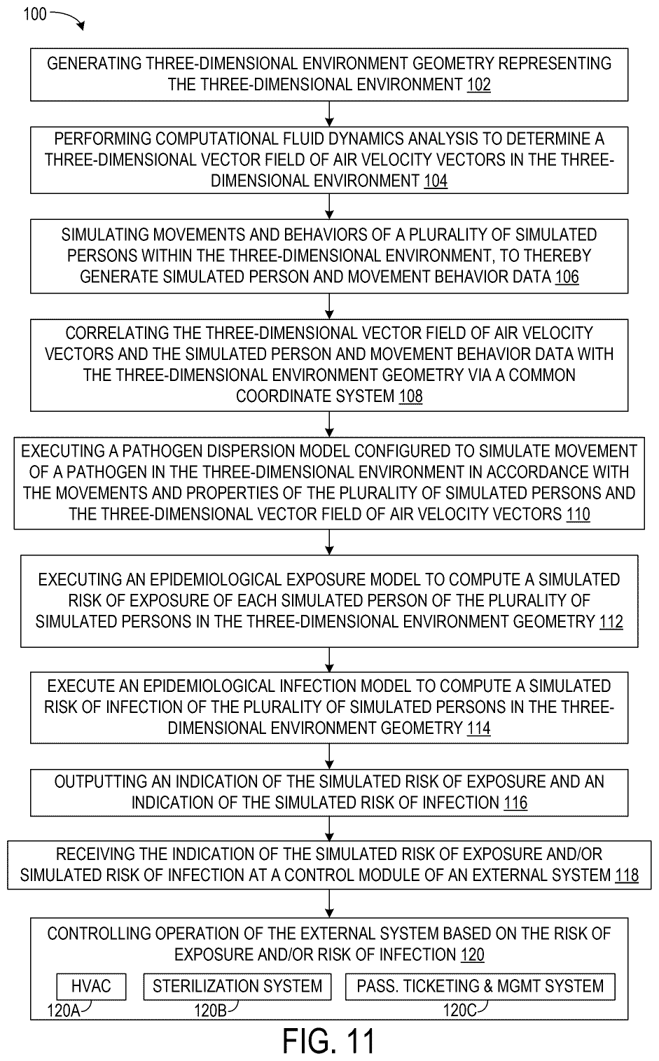

The pathogen transmission modeling program 18 has a plurality of elements, including an environment model 20 that models three-dimensional geometry of the travel environment 5, a computational fluid dynamics (CFD) model 22, a simulated person movement model 24, a pathogen dispersion model 26, an epidemiological exposure and infection dynamics model 28, and an analysis and visualization module 30. These models and module are software elements of the pathogen transmission modeling program 18 and may be implemented on the same or different computing devices, using the same or different instances of the pathogen transmission modeling program. As described in detail below, the pathogen transmission modeling program 18 can additionally ingest data from the travel environment 5, such as data from external air quality sensors 5A and/or external pathogen sensors 5B. Output 32 from the computing system 10 including a simulated risk of exposure 34 and/or a simulated risk of infection 36 can be output, for example to a display 38 or to a downstream program, such as a control module of an external system 40. The manner of computation for these simulated risks of exposure and infection will be described in greater detail with respect to FIG. 2. The output 32 can be used to inform pathogen sensor placement and provide real-time risk analysis and infectious disease prevention recommendations. The output 32 can also be used to control a controlled parameter of the external system 40 in the travel environment 5, as described in further detail below. For example, the external system 40 can be a heating ventilation and air-conditioning (HVAC) system, a sterilizer system, or a passenger management system, as described below in relation to computerized method 100 of FIG. 11.

FIG. 2 shows a schematic diagram of information flow among software elements included in the pathogen transmission modeling program 18 of computing system 10. In FIG. 2, the various machine learning models of computing system 10 are depicted by thick lines. As described in detail below, the CFD model 22 models airflow in various spaces of the three-dimensional environment 5 represented by the three-dimensional environment geometry 20. As described above, the three-dimensional environment can be a travel environment, such as an interior space of an airport gate, ramp, and/or an aircraft cabin. Other travel environments are also envisioned, such as a bus terminal and interior of a bus, a train station and interior of a passenger train, etc. In these examples, the travel environment has a stationary interior space where passengers wait for and board a vehicle, as well as an interior space of the vehicle. The travel environment can also include a movable conveyance to aid passengers in embarking and disembarking the vehicle, such as an aircraft ramp. The three-dimensional environment can also be other community environments in which disease spread is problematic, such as schools, museums, libraries, hospitals, and shopping centers, for example.

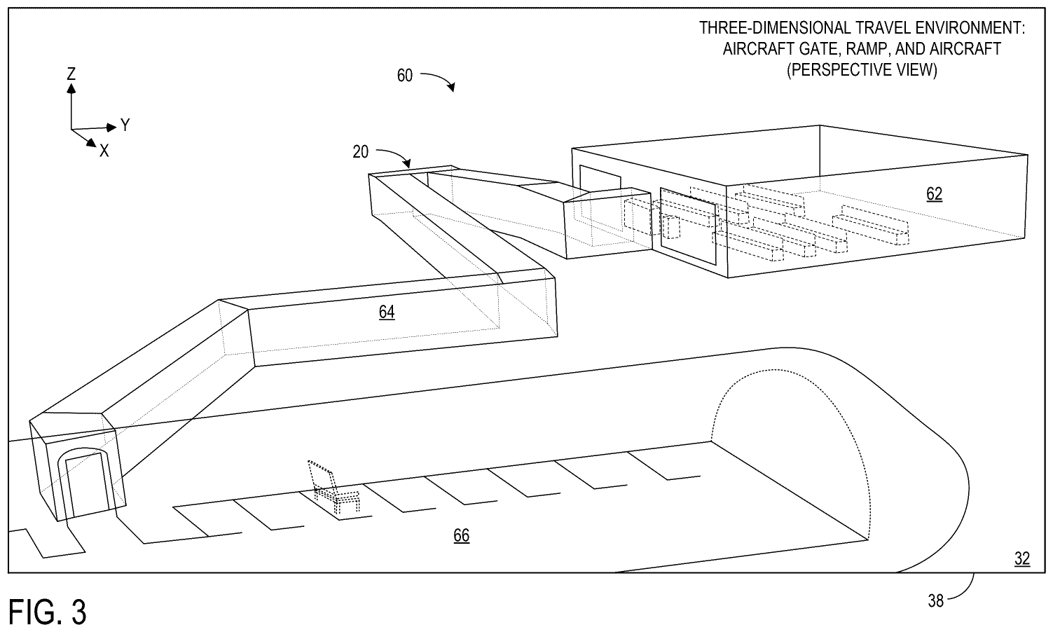

The simulated person movement model 24 models the movement of simulated persons in the three-dimensional environment. In the depicted example of FIGS. 3-10, the movement of passengers, airport employees, cabin crew, and the like is modeled in a travel environment including interior spaces in an aircraft gate, ramp, and aircraft cabin. If desired, risks of transmission to humans from non-human animals that serve as reservoir hosts (i.e., zoonotic spillover) can also be modeled using simulated non-human animal models in addition to the simulated person movement model 24.

Continuing with FIG. 2, the pathogen dispersion model 26 models the movement of a pathogen within the three-dimensional environment, given the airflow predicted by the CFD model 22 and the movements of the simulated persons predicted by the simulated person movement model 24.

The epidemiological exposure and infection dynamics model 28 includes two sub-models: an epidemiological exposure model 28A and an epidemiological infection model 28B, which product model outputs 33. The epidemiological exposure model 28A evaluates (i.e., computes) the exposure of simulated persons to the pathogen in the travel environment, and outputs the simulated risk of exposure 34, as one form of model output 33. The epidemiological infection model 28B evaluates (i.e., computes) the risk of infection of the simulated persons, given the simulated risk of exposure 34, and outputs a simulated risk of infection 36, as another form of model output 33.

The three-dimensional environment 5 represented by three-dimensional environment geometry can be equipped with one or more external air quality sensors 5A and one or more external pathogen sensors 5B, as well as an external system 40 that can be controlled based on the simulated exposure 34 and infection risk 36 computed by the pathogen transmission modeling program 18. The pathogen dispersion model 26 can be configured to receive as input an air quality measurement from the external air quality sensor 5A. In this way the simulated risk of exposure 34 and simulated risk of infection 36 can be computed based on actual measurements of air quality. Similarly, the epidemiological exposure model 28A can be configured to receive as input a pathogen measurement from the external pathogen sensor 5B. In this way the simulated risk of exposure 34 and the simulated risk of infection 36 can be computed based on actual measurements of pathogen in the three-dimensional environment 5.

To allow for a consistent flow of information between each model in the system, standard interfaces (i.e., file formats) are defined to translate information between each model. The interfaces between the models are depicted by rectangles in solid lines with sharp corners in FIG. 2. The three-dimensional environment geometry 20 of the three-dimensional environment 5 is generated with a computer-aided design (CAD) program (e.g., AutoCAD, Solidworks, and other suitable CAD programs) and output to the CFD model 22 and the simulated person movement model 24, for example, in a geometry definition file format (e.g., Wavefront OBJ, Gmsh GEO, and the like).

The CFD model 22 ingests the file(s) containing the three-dimensional geometry 20 representing the three-dimensional environment 5, and performs CFD analysis to produce three-dimensional gridded airflow data 44, which may be stored in files of a suitable standardized format (e.g., OpenFOAM, ANSYS Workbench, NekRS, and the like).

The simulated person movement model 24 ingests the three-dimensional environment geometry 20 and simulates the movement of persons in the three-dimensional environment 5. For example, simulated person movement model 24 can be a simplified microscale social model that simulates movements of persons and the effect such movements have on pathogen transmission, based on behavioral parameters of a population of simulated persons, which are inputted by a user. The overall population of simulated persons can be estimated from ticketed passenger statistics, as well as records for gate staff and crew. For each type of simulated person, a variety of behavior parameters can be supplied. Parameters such as walking speed, age, height, proportion with baggage, and the like can be derived from existing datasets, and parameters such as queueing density, airport activity, social distancing, mask wearing, and the like can be derived from cultural values or human factors studies. Based on these parameters, the simulated person model 24 generates a position, orientation, state (e.g., sitting, standing, walking, eating, etc.), class (e.g., passenger, staff, cabin crew) of each simulated person at a plurality of time steps. Simulated person properties (e.g., age, sex, seat assignment, etc.), surface touches, and close contact/proximity simulated person are generated separately. The simulated person movement model 24 outputs simulated person movement and behavior data 46, in one or more files, each of which can be in comma separated value (CSV) format, for example.

The files for the three-dimensional environment geometry 20, three-dimensional gridded airflow data 44, and simulated person movement and behavior data 46 are correlated using a common coordinate system 48 and output to the pathogen dispersion model 26. An initial pathogen concentration 50 is used to initialize the modeling system. Values for airborne concentrations and surface depositions are generated in three-dimensional gridded files (e.g., OpenFOAM, ANSYS Workbench, NekRS, and the like) and output to the pathogen dispersion model 26.

The pathogen dispersion model 46 processes time steps of the gridded airflow data 44 and the simulated person movement and behavior data 46 and outputs a model of three-dimensional airborne concentration 52 of the pathogen, surface deposition concentration 54 of the pathogen, and fomite transfer of the pathogen over time based on the airflow dynamics and simulated persons movement and behavior data 46. The output may include configurations of which simulated persons are infectious, shedding rates, pathogen particles size, and the like for each time step, as well as air recirculation and filtration parameters. The output for the three-dimensional airborne concentration 52 of the pathogen may be in a three-dimensional gridded file format (e.g., OpenFOAM, ANSYS Workbench, NekRS, and the like), and the output for the surface deposition concentration 54 of the pathogen may be in CSV file format.

The files for simulated person movement and behavior, three-dimensional airborne concentration of the pathogen, and surface concentration of the pathogen are input to the epidemiological exposure model, which determines a pathogen exposure of each simulated person at each time step.

In some implementations, real-time pathogen exposure data may be collected from external pathogen sensors 5B, such as wearable and sentinel surveillance sensor devices. This sensor data can be input to the epidemiological exposure model 28A via a CSV file containing prior exposure data 56 for a simulated person. The simulated person movement and behavior data 46 is augmented with exposure information and output as simulated person exposure risk 34 data. The output may be a CSV file and include a surface-accumulation sub-model and configurations for simulated person inhalation rates, surface transfer rates, and disease parameters, for example. In some implementations, the simulated person exposure risk 34 data may be included in the prior exposure data 56 to link together runs of the model in different areas of the travel environment (e.g., cabin boarding to in-flight) or to include previous exposure outside the travel environment.

The simulated person exposure risk 34 data is output to the epidemiological infection model 28B, which determines a simulated infection risk 36 for each simulated person at each time step of the simulation. The simulated infection risk 36 includes the consideration of diagnostic and public health preventative strategies and is typically expressed as a probability percentage. The simulated person movement and behavior data 46 is augmented with exposure and infection information (i.e., with the simulated exposure risk 34 and simulated infection risk 36) and output to an analysis and visualization module 30 as simulated person infection data. The simulated person movement and behavior data 46 augmented with this risk data may be formatted as a CSV file and include configurations for susceptibility parameters and disease parameters. The analysis and visualization module 30 is configured to display a report 58 including the simulated exposure risk 34 and the simulated infection risk 36 for the simulated persons, and display a two or three-dimensional visualization 60 based on these risks. Examples of such visualizations are described below.

The model outputs 33 can be output to a control module of an external system 40, and used to control the external system, as described below.

Each generated file described above may include metadata, such as a metadata header in JavaScript Object Notation (JSON), format that identifies the processing chain that created the file, including each of the input files that contributed to the processing path, as well as the configuration of each model. The metadata enables a user to open a simulated person infection file and know that it contains the results of a simulation of gate area A, boarding aircraft type B, where simulated person X is infectious with disease Y, and masks were in use, etc. The metadata further enables the development of tools to catalog and organize results sets.

The analysis and visualization module 30 may output analysis and visualization data, including post processing and visualization of CFD and dispersion data, post processing and visualization of simulated person movement data, post processing and visualization of exposure and infection data, and visualizations created with a library of tools to filter, reduce, analyze, compare, chart, and visualize data in 2D and 3D. In some embodiments, the visualization and analysis module 30 may output data to external systems to help mitigate the risk of exposure and infection beyond the travel environment, such as supporting surveillance system planning, providing real-time risk analysis, and providing real-time infectious disease control measure recommendations, for example. Additionally, ingestion of sensor data by models within the framework and output of the models in view of the sensor data establishes a bi-directional data flow between the system and the physical world, which can lead to informing pathogen sensor type and/or placement, determining efficacy of pathogen transmission control strategies that have been implemented in the three-dimensional environment, and optimizing infectious disease control in the three-dimensional environment.

FIG. 3 shows output 32 displayed on display 38 of the computing system, wherein output 32 includes a visualization 60 of the three-dimensional environment geometry 20 in the form of a travel environment, in which the pathogen transmission is to be modeled. In this example, the three-dimensional geometry 20 includes interior spaces of an airport gate area 62, boarding ramp (also referred to as a jet bridge) 64, and aircraft cabin 66. The geometry 20 is utilized by the CFD model 22, simulated person movement model 24, pathogen dispersion model 26, and epidemiological exposure and infection model 28. Coding instructions (e.g., Python scripts) can be used to automate the generation of geometry for indoor spaces. This includes the configuration of room layouts (i.e., physicalized objects like chairs, desks, walls, etc.), air ventilation inlets and outlets used by CFD model 22, and the labeling of surfaces for pathogen surface deposition used in the pathogen dispersion model 26 and epidemiological exposure model 28A. The configuration of a space can be defined by a text file that defines general parameters of an indoor space or aircraft cabin. The auto-generated geometry includes the alignment of different indoor spaces so that these spaces can be connected to one-another, such as the joining of the aircraft gate area 62 with the boarding ramp (jet bridge) 64, and aircraft cabin (interior) 66, for example.

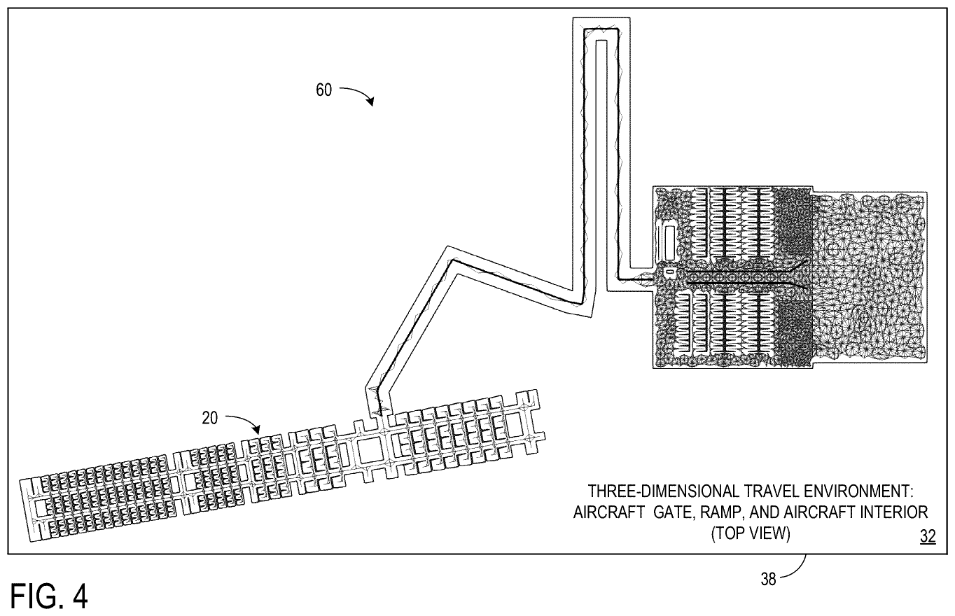

FIG. 4 shows another example of output 32 including a visualization 60 of simulated persons movement and behavior data 46 in the travel environment. The simulated person movement model 24 is used to understand and simulate how individual persons (e.g., passengers, employees, cabin crew, etc.) interact and move through the three-dimensional environment geometry 20 representing. The simulated persons are stochastically built, with individual simulated persons being assigned attributes that determine their interaction and behavior as they move through the indoor space. This modeling includes the ability for simulated persons to navigate spaces over time during the simulation and engage in programmed behaviors such as queuing, seating, boarding the plane, and eating. Each of these behaviors has an associated relative tendency (i.e., a touching rate) for the individual person to touch nearby surfaces. During the simulation, surface touching is tracked for each simulated person and each surface within the three-dimensional environment geometry 20. Operational movement of simulated persons is executed through a general purpose programming language (e.g., C++), in which the timing and navigation of a simulated person are determined. The personal characteristics of simulated persons may be defined using a combination of population and behavioral data sourced from scientific literature and observational behavioral studies, for example.

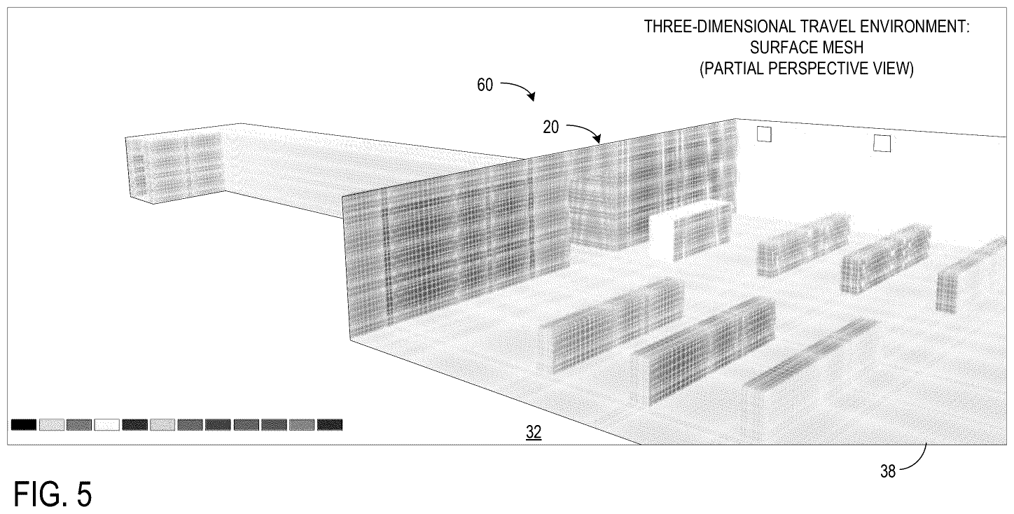

FIG. 5 shows a visualization 60 of a hex mesh of the three-dimensional gridded airflow data 44 generated by the CFD model 22, for a portion of the travel environment represented by the three-dimensional environment geometry 20. By generating such a visualization 60, the steady state air flow and velocity through the travel environment can be simulated. The CFD process implemented by the CFD model 22 involves the meshing of geometry that determines the three-dimensional resolution of the internal geometric cell domain. The more refined and spatially resolved a 3D geometric domain becomes, the greater the computational computing power is required. To achieve a balance between the computational load while maintaining model fidelity and an accurate representation of air flow through the modelled geometry, a semi-automated meshing process is implemented by software (e.g., OpenFOAM) that creates a structured mesh of the internal space of the generated geometry.

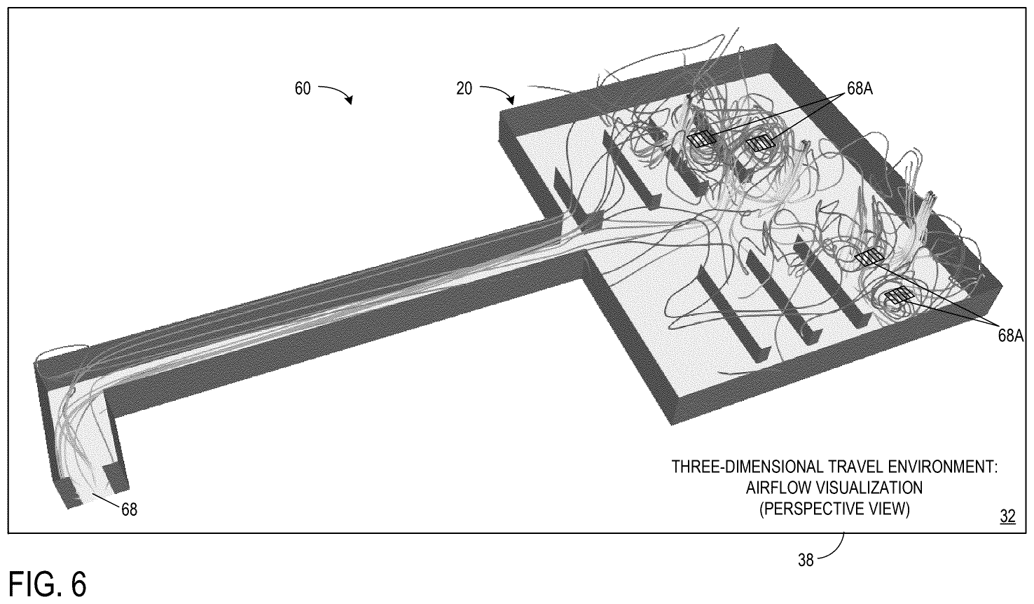

FIG. 6 shows a visualization 60 of air velocity vectors in the travel environment, as produced with the CFD model 22, displayed on display 38. Using defined air inlets and outlets 68, 68A the Reynolds-Averaged Navier-Stokes equation is then used to find statically averaged flow fields of air velocity magnitude by the CFD model 22. It will be appreciated that the inlets and outlets 68A are coupled to an HVAC system, which is an external system 40 as described in FIGS. 1 and 2 above. The control module 42 within the HVAC system can be used to increase air flow flowing through the inlets and outlets 68 when the simulated risk of exposure 34 or simulated risk of infection 36 rises above a predetermined threshold, as described above.

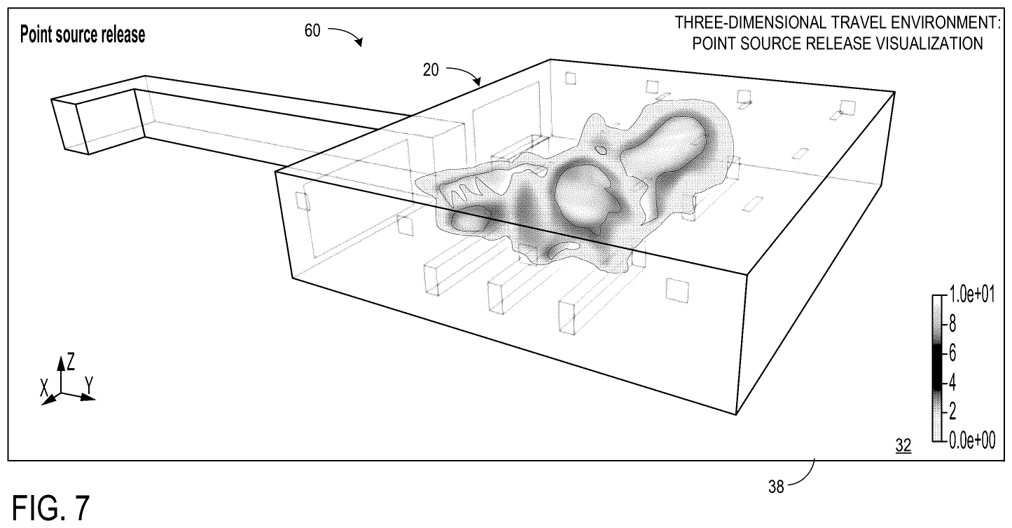

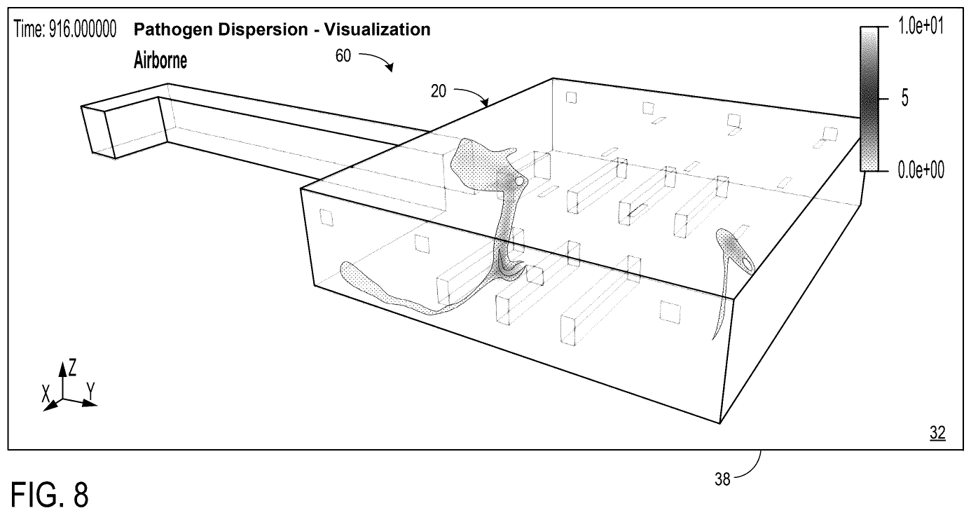

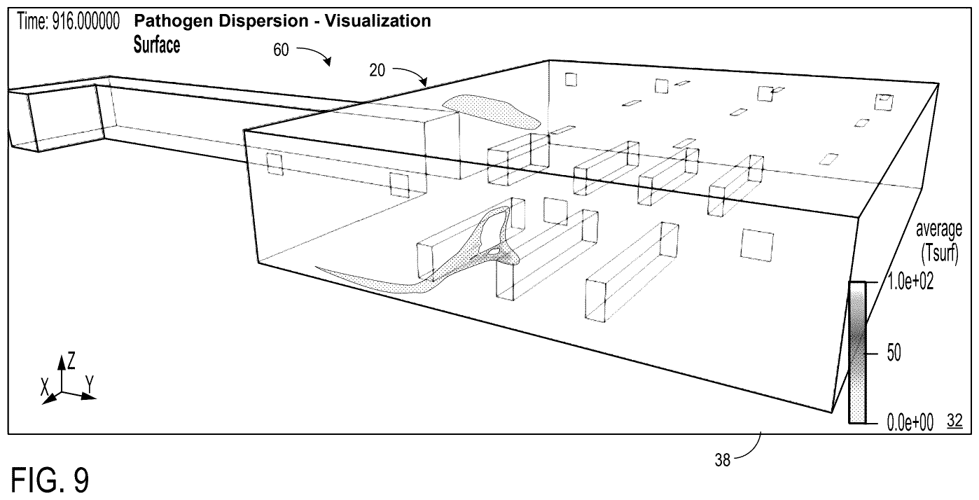

FIGS. 7-9 show respective visualizations 60 of pathogen dispersion in the travel environment displayed on display 38. FIG. 7 shows a visualization 60 of an aerosolized pathogen from a point source release, FIG. 8 shows a diagram of dispersion of an airborne pathogen, and FIG. 9 shows a diagram of dispersion of a fomite-transmissible pathogen. Pathogen dispersion may be modeled using an advection-diffusion-reaction equation, evaluating the dispersion of pathogen concentration in the environment (Equation 1).

$$\frac{\partial C}{\partial t} = ∇ \cdot [ K ∇ C ] - ∇ \cdot ( vC ) + ( {S}_{inf} - {S}_{deact} - {S}_{sett} ) \qquad Equation 1$$

In equation 1, the pathogen concentration for a single cell at a point in time is denoted by ∂C/∂t, this concentration is made of three main components; ∇·[K∇C]] represents the diffusion of the concentration in the 3-dimensional space due to turbulent flow, ∇·(vC) is the advection of concentration due to the velocity of air flow that is derived from the CFD model, and (S_{inf}−S_{deact}−Sₛₑₜₜ) indicates the reaction terms of the pathogen source, deactivation of infectious pathogen, and settling of pathogenic particles, respectively.

Similar to the CFD model 22, the pathogen dispersion model 26 uses the three-dimensional environment geometry 20 to define the environmental boundaries and surface bodies that pathogens can move through and settle onto. The resolution of the internal space in this geometry is taken from the mesh created in the CFD modelling process. The pathogen dispersion model 26 can be run using CFD software (e.g., OpenFOAM), adapting a basic solver (e.g., scalarTransportFoam) to solve the scalar advection-diffusion-reaction equation (Equation 1). From this, the spread and quantification of a pathogen's concentration can be modelled through the three-dimensional environment geometry 20 using the epidemiological exposure model 28A, and infection risk can be modeled based on the exposure modeling results, using epidemiological infection model 28B, as described above.

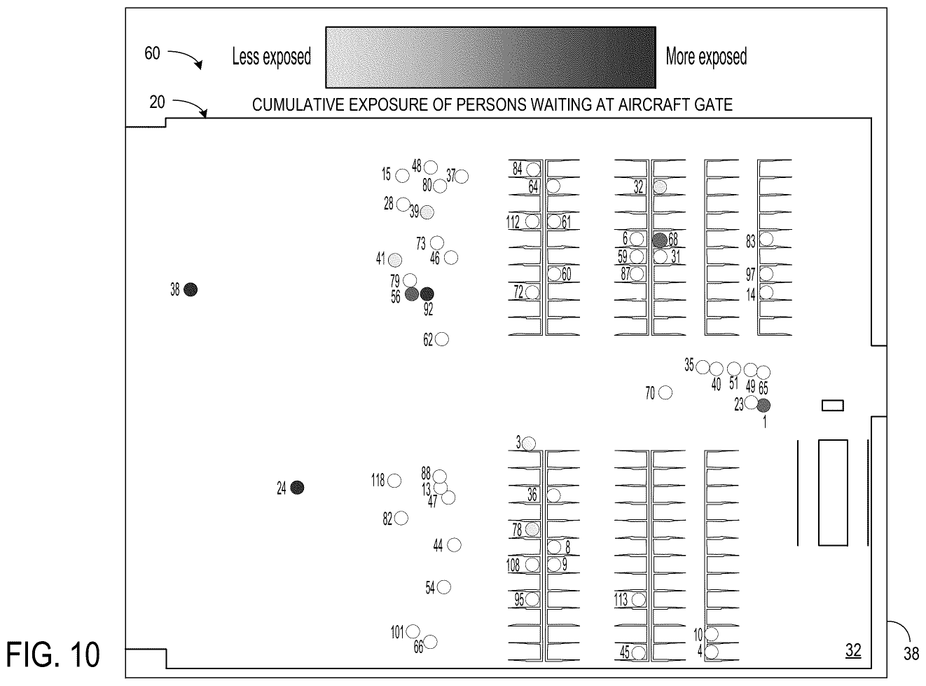

FIG. 10 shows a diagram of exposure of simulated persons in the travel environment. The epidemiological exposure model 28A, connecting the pathogen dispersion model 26 with the simulated person movement model 24, tracks how simulated persons from the simulated person movement model 24 move through and interact with the three-dimensional environment geometry 20 and how they are exposed to the pathogen through aerosolized particles and from direct contact from fomites to quantify their relative cumulative exposure. This is modeled using an integral equation of the following form (Equation 2).

$$Ei ( t ) = \int ( {C}_{i} ( t ) ) dt + \int ( {S}_{i} ( t ) ) dt \qquad Equation 2$$

In Equation 2, Ei(t) is the cumulative concentration of pathogen individual i is exposed to at time t, ∫(Cᵢ(t))dt is the cumulative concentration of pathogen individual i is exposed to from breathing, and ∫(Sᵢ(t))dt is the cumulative concentration of pathogen individual i is exposed to from fomite surfaces.

Pathogen exposure from breathing is expanded (not shown) to account for the relative breathing zone and the phase of tidal breathing using a waveform function. Aerosolized exposure can then be adjusted based on whether the individual is wearing a mask and the relative efficacy of that mask. Pathogen exposure from surface fomites tracks the cumulation and survivability of pathogens on specific surfaces from the settling and deposition from pathogen in the air as wells as for the physical transfer from hands to surfaces. Pathogen inactivation and growth is further considered to determine the final concentration of a pathogen on a surface and an individual contacts that surface. Finally, using behavioral personal characteristics defined in the simulated person model, a pathogen transfer event to a mucosal surface is defined that quantifies the amount of pathogen an individual is exposed from fomites. Risk mitigation activities within this sub-model can include the chemical deactivation of a pathogen from hand sanitation or physical removed during hand washing.

Turning now to FIG. 11, a computerized method 100 for modeling pathogen transmission in a three-dimensional environment according to one example implementation is illustrated. Computerized method 100 can be implemented using the software and hardware components of computing system 10 described above, or with other suitable software and hardware.

Method 100 includes, at 102, generating three-dimensional environment geometry representing the three-dimensional environment. At 104, the method includes performing computational fluid dynamics analysis to determine a three-dimensional vector field of air velocity vectors in the three-dimensional environment using a computational fluid dynamics model. At 106, the method includes simulating movements and behaviors of a plurality of simulated persons within the three-dimensional environment using a simulated person movement model, to thereby generate simulated person and movement behavior data.

At 108, the method includes correlating the three-dimensional vector field of air velocity vectors and the simulated person and movement behavior data with the three-dimensional environment geometry via a common coordinate system. As described above, three-dimensional environment geometry can be a travel environment, which can include interior spaces of an aircraft gate, ramp, and aircraft cabin, for example. At 110, the method includes executing a pathogen dispersion model configured to simulate movement of a pathogen in the three-dimensional environment in accordance with the movements and properties of the plurality of simulated persons and the three-dimensional vector field of air velocity vectors. At 112, the method includes executing an epidemiological exposure model to compute a simulated risk of exposure of each simulated person of the plurality of simulated persons in the three-dimensional environment geometry. At 114, the method includes executing an epidemiological infection model to compute a simulated risk of infection of the plurality of simulated persons in the three-dimensional environment geometry. Finally, at 116, the method includes outputting an indication of the simulated risk of exposure and an indication of the simulated risk of infection.

At 118, the method further includes receiving the indication of the simulated risk of exposure and/or simulated risk of infection at a control module of an external system. At 120, the method further includes controlling operation of the external system based on the risk of exposure and/or risk of infection.

As shown at 120A, the external system can be a heating ventilation and air conditioning (HVAC) system, and the control module can be configured to increase airflow through the three-dimensional environment in response to the simulated risk of exposure and/or simulated risk of infection exceeding a predetermined threshold.

As shown at 120B, the external system can be a sterilization system, and the control module can be configured to cause the sterilization system to sterilize surfaces and/or airflow in the three-dimensional environment in response to the risk of exposure and/or risk of infection exceeding a predetermined threshold. The sterilization system can utilize, for example, UV sterilizer lights configured to render pathogens harmless through irradiation. The UV sterilizer lights can be positioned in an airway of an HVAC system, at fixed locations within the environment, or on a mobile robot that travels through the three-dimensional environment to pathogen hotspots, for example.

As shown at 120C, the external system can be a passenger ticketing and management system and the control module can be configured to cause the passenger ticketing and management system to schedule the movement of passengers through the three-dimensional environment to increase the spatiotemporal density of the passengers in the environment, and/or route passengers around pathogen hotspots on surfaces or in the airflow in the three-dimensional environment. This can be achieved, for example, by specifying different times at which passengers can move throughout the three-dimensional environment. One example of this is that passengers can be called to board in boarding groups at a timing and of a group size that minimizes passenger density. Another example of this is that groups can be told to line up flexibly at different predetermined locations within the three-dimensional environment, and the locations can be selected as areas with low pathogen detection, to decrease pathogen hotspots. As another example, passengers can be told to arrive at the gate in timed groups or told that they can stand up and move around the aircraft cabin in timed groups, to minimize congestion and increase spatiotemporal density.

It will be appreciated that the three-dimensional environment can be equipped with an external air quality sensor and the pathogen dispersion model can be configured to receive as input an air quality measurement from the external air quality sensor. In this way the risk of exposure and infection can be computed based on actual measurements of air quality. Similarly, the three-dimensional environment can be equipped with an external pathogen sensor, and the epidemiological exposure model can be configured to receive as input a pathogen measurement from the external pathogen sensor. In this way the risk of exposure and infection can be computed based on actual measurements of pathogen in the three-dimensional environment.

In some embodiments, the methods and processes described herein may be tied to a computing system of one or more computing devices. In particular, such methods and processes may be implemented as a computer-application program or service, an application-programming interface (API), a library, and/or other computer-program product.

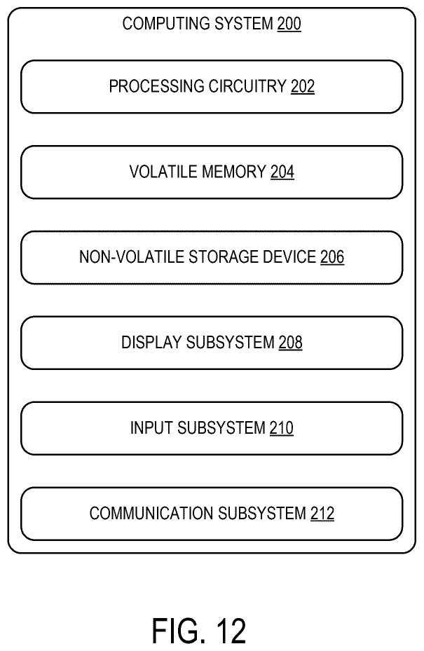

FIG. 12 schematically shows a non-limiting embodiment of a computing system 200 that can enact one or more of the methods and processes described above. Computing system 200 is shown in simplified form. Computing system 200 may embody the computing system 10 described above and illustrated in FIG. 1. Components of computing system 200 may be included in one or more personal computers, server computers, tablet computers, home-entertainment computers, network computing devices, video game devices, mobile computing devices, mobile communication devices (e.g., smartphone), and/or other computing devices, and wearable computing devices such as smart wristwatches and head mounted augmented reality devices.

Computing system 200 includes a logic processor 202 volatile memory 204, and a non-volatile storage device 206. Computing system 200 may optionally include a display subsystem 208, input subsystem 210, communication subsystem 212, and/or other components not shown in FIG. 12.

Logic processor 202 includes one or more physical devices configured to execute instructions. For example, the logic processor may be configured to execute instructions that are part of one or more applications, programs, routines, libraries, objects, components, data structures, or other logical constructs. Such instructions may be implemented to perform a task, implement a data type, transform the state of one or more components, achieve a technical effect, or otherwise arrive at a desired result.

The logic processor may include one or more physical processors configured to execute software instructions. Additionally or alternatively, the logic processor may include one or more hardware logic circuits or firmware devices configured to execute hardware-implemented logic or firmware instructions. Processors of the logic processor 202 may be single-core or multi-core, and the instructions executed thereon may be configured for sequential, parallel, and/or distributed processing. Individual components of the logic processor optionally may be distributed among two or more separate devices, which may be remotely located and/or configured for coordinated processing. Aspects of the logic processor may be virtualized and executed by remotely accessible, networked computing devices configured in a cloud-computing configuration. In such a case, these virtualized aspects are run on different physical logic processors of various different machines, it will be understood.

Non-volatile storage device 206 includes one or more physical devices configured to hold instructions executable by the logic processors to implement the methods and processes described herein. When such methods and processes are implemented, the state of non-volatile storage device 206 may be transformed—e.g., to hold different data.

Non-volatile storage device 206 may include physical devices that are removable and/or built in. Non-volatile storage device 206 may include optical memory, semiconductor memory, and/or magnetic memory, or other mass storage device technology. Non-volatile storage device 206 may include nonvolatile, dynamic, static, read/write, read-only, sequential-access, location-addressable, file-addressable, and/or content-addressable devices. It will be appreciated that non-volatile storage device 206 is configured to hold instructions even when power is cut to the non-volatile storage device 206.

Volatile memory 204 may include physical devices that include random access memory. Volatile memory 204 is typically utilized by logic processor 202 to temporarily store information during processing of software instructions. It will be appreciated that volatile memory 204 typically does not continue to store instructions when power is cut to the volatile memory 204.

Aspects of logic processor 202, volatile memory 204, and non-volatile storage device 206 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

The terms “module,” “program,” and “engine” may be used to describe an aspect of computing system 200 typically implemented in software by a processor to perform a particular function using portions of volatile memory, which function involves transformative processing that specially configures the processor to perform the function. Thus, a module, program, or engine may be instantiated via logic processor 202 executing instructions held by non-volatile storage device 206, using portions of volatile memory 204. It will be understood that different modules, programs, and/or engines may be instantiated from the same application, service, code block, object, library, routine, API, function, etc. Likewise, the same module, program, and/or engine may be instantiated by different applications, services, code blocks, objects, routines, APIs, functions, etc. The terms “module,” “program,” and “engine” may encompass individual or groups of executable files, data files, libraries, drivers, scripts, database records, etc.

When included, display subsystem 208 may be used to present a visual representation of data held by non-volatile storage device 206. The visual representation may take the form of a graphical user interface (GUI). As the herein described methods and processes change the data held by the non-volatile storage device, and thus transform the state of the non-volatile storage device, the state of display subsystem 208 may likewise be transformed to visually represent changes in the underlying data. Display subsystem 208 may include one or more display devices utilizing virtually any type of technology. Such display devices may be combined with logic processor 202, volatile memory 204, and/or non-volatile storage device 206 in a shared enclosure, or such display devices may be peripheral display devices.

When included, input subsystem 210 may comprise or interface with one or more user-input devices such as a keyboard, mouse, touch screen, camera, or microphone.

When included, communication subsystem 212 may be configured to communicatively couple various computing devices described herein with each other, and with other devices. Communication subsystem 212 may include wired and/or wireless communication devices compatible with one or more different communication protocols. As non-limiting examples, the communication subsystem may be configured for communication via a wired or wireless local- or wide-area network, broadband cellular network, etc. In some embodiments, the communication subsystem may allow computing system 200 to send and/or receive messages to and/or from other devices via a network such as the Internet.

Further, the disclosure comprises configurations according to the following examples.

Example 1. A computing system for modeling pathogen transmission in a three-dimensional environment, the computing system comprising: processing circuitry configured to implement the pathogen transmission modeling program stored in memory, thereby causing the processing circuitry to: generate three-dimensional environment geometry representing the three-dimensional environment; perform computational fluid dynamics analysis to determine a three-dimensional vector field of air velocity vectors in the three-dimensional environment using a computational fluid dynamics model; simulate movements and behaviors of a plurality of simulated persons within the three-dimensional environment using a simulated person movement model, to thereby generate simulated person and movement behavior data; correlate the three-dimensional vector field of air velocity vectors and the simulated person and movement behavior data with the three-dimensional environment geometry via a common coordinate system; execute a pathogen dispersion model configured to simulate movement of a pathogen in the three-dimensional environment in accordance with the movements and properties of the plurality of simulated persons and the three-dimensional vector field of air velocity vectors; execute an epidemiological exposure model to compute a simulated risk of exposure of each simulated person of the plurality of simulated persons in the three-dimensional environment geometry; and output an indication of the simulated risk of exposure.

Example 2. The computing system of example 1, wherein the processing circuitry is further configured to: execute an epidemiological infection model to compute a simulated risk of infection of the plurality of simulated persons in the three-dimensional environment geometry; and output an indication of the simulated risk of infection.

Example 3. The computing system of examples 1 or 2, wherein the three-dimensional environment geometry is a travel environment.

Example 4. The computing system of example 3, wherein the travel environment includes interior spaces of an aircraft gate, ramp, and aircraft cabin.

Example 5. The computing system of example 2, wherein the computing system further comprises an external system configured to: receive the indication of the simulated risk of exposure and/or simulated risk of infection at a control module of the external system; and control operation of the external system based on the risk of exposure and/or risk of infection.

Example 6. The computing system of example 5, wherein the external system is a heating ventilation and air conditioning system, and the control module is configured to increase airflow through the three-dimensional environment in response to the simulated risk of exposure and/or simulated risk of infection exceeding a predetermined threshold.

Example 7. The computing system of example 5, wherein the external system is a sterilization system, and the control module is configured to cause the sterilization system to sterilize surfaces and/or airflow in the three-dimensional environment in response to the risk of exposure and/or risk of infection exceeding a predetermined threshold.

Example 8. The computing system of example 5, wherein the external system is a passenger ticketing and management system and the control module is configured to cause the passenger ticketing and management system to schedule the movement of passengers through the three-dimensional environment to increase the spatiotemporal density of the passengers in the environment, and/or route passengers around pathogen hotspots on surfaces or in the airflow in the three-dimensional environment.

Example 9. The computing system of any one of examples 1-8, wherein the three-dimensional environment is equipped with an external air quality sensor and the pathogen dispersion model is configured to receive as input an air quality measurement from the external air quality sensor; and/or the three-dimensional environment is equipped with an external pathogen sensor, and the epidemiological exposure model is configured to receive as input a pathogen measurement from the external pathogen sensor.

Example 10. A computerized method for modeling pathogen transmission in a three-dimensional environment, the computerized method comprising: generating three-dimensional environment geometry representing the three-dimensional environment; performing computational fluid dynamics analysis to determine a three-dimensional vector field of air velocity vectors in the three-dimensional environment using a computational fluid dynamics model; simulating movements and behaviors of a plurality of simulated persons within the three-dimensional environment using a simulated person movement model, to thereby generate simulated person and movement behavior data; correlating the three-dimensional vector field of air velocity vectors and the simulated person and movement behavior data with the three-dimensional environment geometry via a common coordinate system; executing a pathogen dispersion model configured to simulate movement of a pathogen in the three-dimensional environment in accordance with the movements and properties of the plurality of simulated persons and the three-dimensional vector field of air velocity vectors; executing an epidemiological exposure model to compute a simulated risk of exposure of each simulated person of the plurality of simulated persons in the three-dimensional environment geometry; and outputting an indication of the simulated risk of exposure.

Example 11. The computerized method of example 10, further comprising: executing an epidemiological infection model to compute a simulated risk of infection of the plurality of simulated persons in the three-dimensional environment geometry; and outputting an indication of the simulated risk of infection.

Example 12. The computerized method of example 10 or 11, wherein the three-dimensional environment geometry is a travel environment.

Example 13. The computerized method of example 12, wherein the travel environment includes interior spaces of an aircraft gate, ramp, and aircraft cabin.

Example 14. The computerized method of example 11, further comprising: receiving the indication of the simulated risk of exposure and/or simulated risk of infection at a control module of an external system; and controlling operation of the external system based on the risk of exposure and/or risk of infection.

Example 15. The computerized method of example 14, wherein the external system is a heating ventilation and air conditioning system and the control module is configured to increase airflow through the three-dimensional environment in response to the simulated risk of exposure and/or simulated risk of infection exceeding a predetermined threshold.

Example 16. The computerized method of example 14, wherein the external system is a sterilization system and the control module is configured to cause the sterilization system to sterilize surfaces and/or airflow in the three-dimensional environment in response to the risk of exposure and/or risk of infection exceeding a predetermined threshold.

Example 17. The computerized method of example 14, wherein the external system is a passenger ticketing and management system and the control module is configured to cause the passenger ticketing and management system to schedule the movement of passengers through the three-dimensional environment to increase the spatiotemporal density of the passengers in the environment, and/or route passengers around pathogen hotspots on surfaces or in the airflow in the three-dimensional environment.

Example 18. The computerized method of any one of examples 10-17, wherein the three-dimensional environment is equipped with an external air quality sensor and the pathogen dispersion model is configured to receive as input an air quality measurement from the external air quality sensor.

Example 19. The computerized method of any one of examples 10-18, wherein the three-dimensional environment is equipped with an external pathogen sensor, and the epidemiological exposure model is configured to receive as input a pathogen measurement from the external pathogen sensor.

Example 20. A computing system for modeling pathogen transmission in a three-dimensional environment, the computing system comprising: processing circuitry configured to implement a pathogen transmission modeling program stored in memory, thereby causing the processing circuitry to: generate three-dimensional environment geometry representing the three-dimensional environment, wherein the three-dimensional environment is a travel environment; perform computational fluid dynamics analysis to determine a three-dimensional vector field of air velocity vectors in the three-dimensional environment using a computational fluid dynamics model; simulate movements and behaviors of a plurality of simulated persons within the three-dimensional environment using a simulated person movement model, to thereby generate simulated person and movement behavior data; correlate the three-dimensional vector field of air velocity vectors and the simulated person and movement behavior data with the three-dimensional environment geometry via a common coordinate system; execute a pathogen dispersion model configured to simulate movement of a pathogen in the three-dimensional environment in accordance with the movements and properties of the plurality of simulated persons and the three-dimensional vector field of air velocity vectors; execute an epidemiological exposure model to compute a simulated risk of exposure of each simulated person of the plurality of simulated persons in the three-dimensional environment geometry; execute an epidemiological infection model to compute a simulated risk of infection of the plurality of simulated persons in the three-dimensional environment geometry; output an indication of the simulated risk of exposure and an indication of the simulated risk of infection; receiving the indication of the simulated risk of exposure and/or simulated risk of infection at a control module of an external system; and controlling operation of the external system based on the risk of exposure and/or risk of infection.

And/or” as used herein is defined as the inclusive or ∨, as specified by the following truth table:

| A | B | A ∨ B |
|---|---|---|
| True | True | True |
| True | False | True |
| False | True | True |
| False | False | False |

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A computing system for modeling pathogen transmission in a three-dimensional environment, the computing system comprising:
processing circuitry configured to implement the pathogen transmission modeling program stored in memory, thereby causing the processing circuitry to:
generate three-dimensional environment geometry representing the three-dimensional environment;
perform computational fluid dynamics analysis to determine a three-dimensional vector field of air velocity vectors in the three-dimensional environment using a computational fluid dynamics model;
simulate movements and behaviors of a plurality of simulated persons within the three-dimensional environment using a simulated person movement model, to thereby generate simulated person and movement behavior data;
correlate the three-dimensional vector field of air velocity vectors and the simulated person and movement behavior data with the three-dimensional environment geometry via a common coordinate system;
execute a pathogen dispersion model configured to simulate movement of a pathogen in the three-dimensional environment in accordance with the movements and properties of the plurality of simulated persons and the three-dimensional vector field of air velocity vectors;
execute an epidemiological exposure model to compute a simulated risk of exposure of each simulated person of the plurality of simulated persons in the three-dimensional environment geometry; and
output an indication of the simulated risk of exposure.

2. The computing system of claim 1, wherein the processing circuitry is further configured to:
execute an epidemiological infection model to compute a simulated risk of infection of the plurality of simulated persons in the three-dimensional environment geometry; and
output an indication of the simulated risk of infection.

3. The computing system of claim 1, wherein the three-dimensional environment geometry is a travel environment.

4. The computing system of claim 3, wherein the travel environment includes interior spaces of an aircraft gate, ramp, and aircraft cabin.

5. The computing system of claim 2, wherein the computing system further comprises an external system configured to:
receive the indication of the simulated risk of exposure and/or simulated risk of infection at a control module of the external system; and
control operation of the external system based on the risk of exposure and/or risk of infection.

6. The computing system of claim 5, wherein the external system is a heating ventilation and air conditioning system, and the control module is configured to increase airflow through the three-dimensional environment in response to the simulated risk of exposure and/or simulated risk of infection exceeding a predetermined threshold.

7. The computing system of claim 5, wherein the external system is a sterilization system, and the control module is configured to cause the sterilization system to sterilize surfaces and/or airflow in the three-dimensional environment in response to the risk of exposure and/or risk of infection exceeding a predetermined threshold.

8. The computing system of claim 5, wherein the external system is a passenger ticketing and management system and the control module is configured to cause the passenger ticketing and management system to schedule the movement of passengers through the three-dimensional environment to increase the spatiotemporal density of the passengers in the environment, and/or route passengers around pathogen hotspots on surfaces or in the airflow in the three-dimensional environment.

9. The computing system of claim 1, wherein
the three-dimensional environment is equipped with an external air quality sensor and the pathogen dispersion model is configured to receive as input an air quality measurement from the external air quality sensor; and/or
the three-dimensional environment is equipped with an external pathogen sensor, and the epidemiological exposure model is configured to receive as input a pathogen measurement from the external pathogen sensor.

10. A computerized method for modeling pathogen transmission in a three-dimensional environment, the computerized method comprising:
generating three-dimensional environment geometry representing the three-dimensional environment;
performing computational fluid dynamics analysis to determine a three-dimensional vector field of air velocity vectors in the three-dimensional environment using a computational fluid dynamics model;
simulating movements and behaviors of a plurality of simulated persons within the three-dimensional environment using a simulated person movement model, to thereby generate simulated person and movement behavior data;
correlating the three-dimensional vector field of air velocity vectors and the simulated person and movement behavior data with the three-dimensional environment geometry via a common coordinate system;
executing a pathogen dispersion model configured to simulate movement of a pathogen in the three-dimensional environment in accordance with the movements and properties of the plurality of simulated persons and the three-dimensional vector field of air velocity vectors;
executing an epidemiological exposure model to compute a simulated risk of exposure of each simulated person of the plurality of simulated persons in the three-dimensional environment geometry; and
outputting an indication of the simulated risk of exposure.

11. The computerized method of claim 10, further comprising:
executing an epidemiological infection model to compute a simulated risk of infection of the plurality of simulated persons in the three-dimensional environment geometry; and
outputting an indication of the simulated risk of infection.

12. The computerized method of claim 10, wherein the three-dimensional environment geometry is a travel environment.

13. The computerized method of claim 12, wherein the travel environment includes interior spaces of an aircraft gate, ramp, and aircraft cabin.

14. The computerized method of claim 11, further comprising:
receiving the indication of the simulated risk of exposure and/or simulated risk of infection at a control module of an external system; and
controlling operation of the external system based on the risk of exposure and/or risk of infection.

15. The computerized method of claim 14, wherein the external system is a heating ventilation and air conditioning system and the control module is configured to increase airflow through the three-dimensional environment in response to the simulated risk of exposure and/or simulated risk of infection exceeding a predetermined threshold.

16. The computerized method of claim 14, wherein the external system is a sterilization system and the control module is configured to cause the sterilization system to sterilize surfaces and/or airflow in the three-dimensional environment in response to the risk of exposure and/or risk of infection exceeding a predetermined threshold.

17. The computerized method of claim 14, wherein the external system is a passenger ticketing and management system and the control module is configured to cause the passenger ticketing and management system to schedule the movement of passengers through the three-dimensional environment to increase the spatiotemporal density of the passengers in the environment, and/or route passengers around pathogen hotspots on surfaces or in the airflow in the three-dimensional environment.

18. The computerized method of claim 10, wherein the three-dimensional environment is equipped with an external air quality sensor and the pathogen dispersion model is configured to receive as input an air quality measurement from the external air quality sensor.

19. The computerized method of claim 10, wherein the three-dimensional environment is equipped with an external pathogen sensor, and the epidemiological exposure model is configured to receive as input a pathogen measurement from the external pathogen sensor.

20. A computing system for modeling pathogen transmission in a three-dimensional environment, the computing system comprising:
processing circuitry configured to implement a pathogen transmission modeling program stored in memory, thereby causing the processing circuitry to:
generate three-dimensional environment geometry representing the three-dimensional environment, wherein the three-dimensional environment is a travel environment;
perform computational fluid dynamics analysis to determine a three-dimensional vector field of air velocity vectors in the three-dimensional environment using a computational fluid dynamics model;
simulate movements and behaviors of a plurality of simulated persons within the three-dimensional environment using a simulated person movement model, to thereby generate simulated person and movement behavior data;
correlate the three-dimensional vector field of air velocity vectors and the simulated person and movement behavior data with the three-dimensional environment geometry via a common coordinate system;
execute a pathogen dispersion model configured to simulate movement of a pathogen in the three-dimensional environment in accordance with the movements and properties of the plurality of simulated persons and the three-dimensional vector field of air velocity vectors;
execute an epidemiological exposure model to compute a simulated risk of exposure of each simulated person of the plurality of simulated persons in the three-dimensional environment geometry;
execute an epidemiological infection model to compute a simulated risk of infection of the plurality of simulated persons in the three-dimensional environment geometry;
output an indication of the simulated risk of exposure and an indication of the simulated risk of infection;
receiving the indication of the simulated risk of exposure and/or simulated risk of infection at a control module of an external system; and
controlling operation of the external system based on the risk of exposure and/or risk of infection.
